(19) United States
(12) Patent Application Publication
(10) Pub. No.: US 2026/0118447 A1
(43) Pub. Date: Apr. 30, 2026

(54) Portable Quantum Sensing Device

(71) Applicant: Morgan State University, Baltimore, MD (US)

(72) Inventors: Birol Ozturk, Baltimore, MD (US); Peker Milas, Baltimore, MD (US); Tomas Sujeta, Baltimore, MD (US); Sheikh Shahparan Mahtab, Baltimore, MD (US)

(21) Appl. No.: 18/921,456

(22) Filed: Oct. 21, 2024

Related U.S. Application Data
(60) Provisional application No. 63/545,042, filed on Oct. 20, 2023.

(51) Int. Cl. G01R 33/032

(52) U.S. Cl. CPC G01R 33/032

(57) ABSTRACT

A compact portable quantum sensor device consists of a very high efficiency RF antenna, a low power RF signal generator, an RF amplifier (if needed), an RF switch and isolator, a photodetector(s) with amplifier circuit, various optical components, a microcontroller, a Bluetooth communication board, a battery, a display, and control software and machine learning algorithms for noise reduction and data analysis. A battery-operated portable quantum sensor device prototype was built for magnetometry applications. A second prototype with a smaller sensor head footprint was also built for brain imaging through measuring magnetic fields induced by brain neuron action potentials. In a third photonic circuit approach, all of the optical and electronic components are integrated on the same chip.

### STATEMENT OF GOVERNMENT INTEREST

This invention was made in part with government support under grant number 2101102 awarded by the National Science Foundation. The government has certain rights in the invention.

### FIELD OF THE INVENTION

The present invention relates to quantum sensing devices.

### BACKGROUND OF THE INVENTION

Quantum sensing, among the diverse range of emerging quantum science applications such as computing and communication, is gaining increasing recognition as a viable technology, with commercially available benchtop products already making their mark in the market. It relies on the intrinsic sensitivities of quantum state to their surrounding environment to detect extremely small changes in temperature, magnetic, and electric fields. Nitrogen vacancy (NV) color center defects in diamond have recently drawn considerable attention as a solid-state quantum sensing platform that, unlike many other systems, can operate under ambient conditions. The transformative potential of this quantum sensing approach has been primarily demonstrated at picotesla (pT) level and high spatial resolution magnetometry. The physical dimensions of the current laboratory setups or the few commercially available benchtop systems inhibit the potential utilization of NV diamond-based quantum sensors in a wide range of applications. Although there have been many attempts by various research groups worldwide to miniaturize the diamond-based quantum sensor devices, a compact handheld quantum sensor for magnetic field sensing has not been demonstrated.

Magnetoencephalography (MEG) is used to identify or map the functional regions of the brain, such as those related to sensory, motor, language, and memory functions, as well as to precisely locate the origin of epileptic seizures. MEG is used to generate a comprehensive brain map for preoperative assessments and treatment planning for individuals with epilepsy. Additionally, MEG aids in surgical procedures for the removal of brain tumors or other lesions by providing crucial information for surgical planning. Current standard-of-care for the treatment planning methods are electroencephalography (EEG) and superconductivity-based MEG. EEGs have less spatial resolution, localization accuracy, and sensitivity to deep brain structures than MEGs. Superconductivity based MEGs are expensive and they require costly cryogenics to operate. They also require special magnetically shielded rooms to operate. Optically Pumped Magnetometer (OPMs) have recently emerged as alternative MEGs. However, they operate at elevated temperatures (150° C.) and they also need magnetically shield rooms.

### SUMMARY OF THE INVENTION

To address the deficiencies of the prior art, there is provided according to the invention a quantum sensing device including: a housing, a power source, a computer processor and non-transient memory, an RF signal generator, an RF amplifier, an RF switch, an analog-to-digital converter, a display, an input device, and an optics module, the optics module comprising, a laser driver circuit, a laser, at least one lens configured to focus excitation laser on the diamond sample, a diamond located in an optical path of the laser, at least one optical filter configured to filter the excitation laser, and a photodiode configured to collect emitted signals by the diamond, the non-transient memory containing computer readable instructions which when executed by the computer processor cause the power source to turn on the laser, the display device to turn on and accept user instructions, the RF signal generator to turn on and start the RF frequency sweep at a predetermined or user-selected amplitude, the RF amplifier to power on, the RF switch to allow applications of RF signals at predetermined or user-selected intervals, the analog-to-digital converter to transmit converted digital signals at predetermined or user-selected intervals, and the optics module to perform ODMR measurements.

According to various embodiments of the invention, the device may be portable and compact with a size no greater than 23 cubic inches, where the power source, the RF signal generator, the RF amplifier, the RF switch, the analog-to-digital converter, the display, the input device, and the optics module, are all contained in or on a single housing.

The quantum sensing device of the invention may be configured to detect microtesla, nanotesla, picotesla, and/or femtotesla level magnetic fields and their vectorial components.

According to a specialized embodiment for brain measurements, the device may have a sensor head comprising only the RF antenna and the diamond, the sensor head connected to the spectrometer or photodiode by an optical fiber RF cable. Alternatively, the sensor head may have a photodiode, in which case the sensor head is connected to the computer processor by an RF cable and/or other data cables.

CQS devices of the invention have significant and valuable applications in numerous fields, including but not limited to GPS denied navigation, medicine, biomedical, integrated circuit nondestructive analysis, nuclear forensics, and space exploration.

### BRIEF DESCRIPTION OF THE DRAWINGS

FIG. 1A is a photograph of a portable quantum sensing device according to an embodiment of the invention.

FIG. 1B is a schematic showing the dimensions of an optics module design according to an embodiment of the invention.

FIG. 1C is a chart showing simulated and measured return losses (S11) of a high efficiency omega shaped coplanar RF antenna.

FIG. 1D shows the antenna's dimensions and the simulated magnetic field image according to an embodiment of the invention.

FIG. 2A is a chart showing data from an ODMR scan collected with the CQS device. Two dips and additional features are visible due to the vectorial nature of the externally applied magnetic field.

FIG. 2B is a chart showing a comparison of the applied (green) and machine learning model predicted (red) vectorial magnetic field vector for the ODMR scan of FIG. 2A. Each axis in this graph represents applied currents to the Helmholtz coils while applying the controlled external magnetic field. In each axis, the range of −1 to 1 corresponds to a range of −500 to 500 microtesla.

FIG. 3A is a representation of an electronic board of another embodiment of a compact quantum sensor (CQS) device according to the invention showing an optics module with attached red colored optics module.

FIG. 3B shows a commercial Hammond box that may be used as a housing for the embodiment of FIG. 3A.

FIG. 4A shows a third embodiment of a compact quantum sensor device according to the invention.

FIG. 4B is a graph showing microtesla level magnetic field sensing with a fiber quantum sensor prototype according to the invention, where the magnetic field is generated by an electromagnet in the head phantom as shown in FIG. 4A.

FIG. 5 is a schematic diagram of a PIC diamond magnetometer design according to an embodiment of the invention in which the components are coplanar.

FIG. 6 is a schematic diagram of a PIC grating coupled diamond magnetometer according to another embodiment of the invention in which tilted diode laser and photodiode are coupled to waveguides via grating couplers.

### DETAILED DESCRIPTION OF THE INVENTION

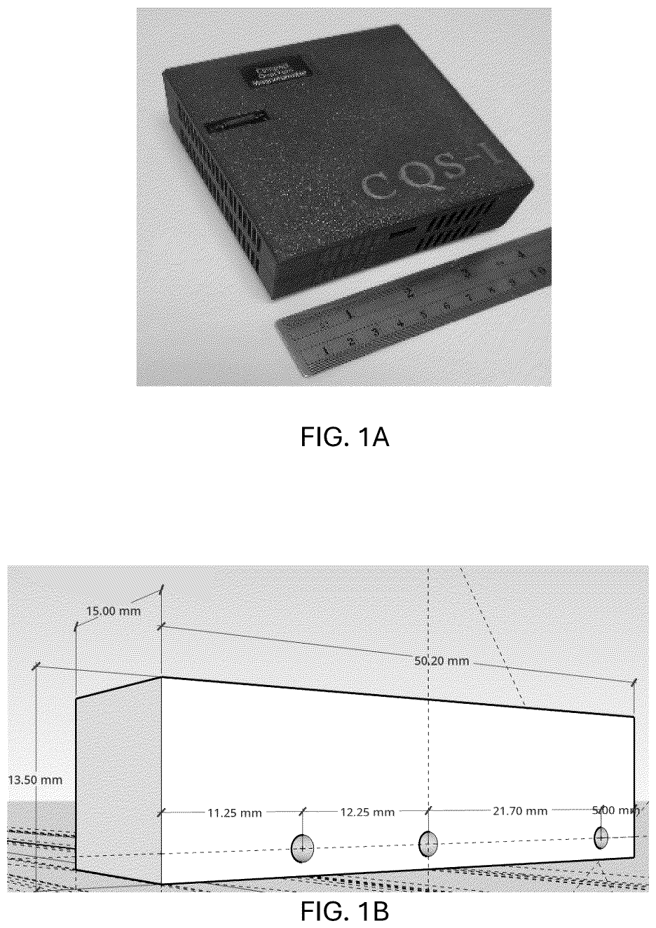

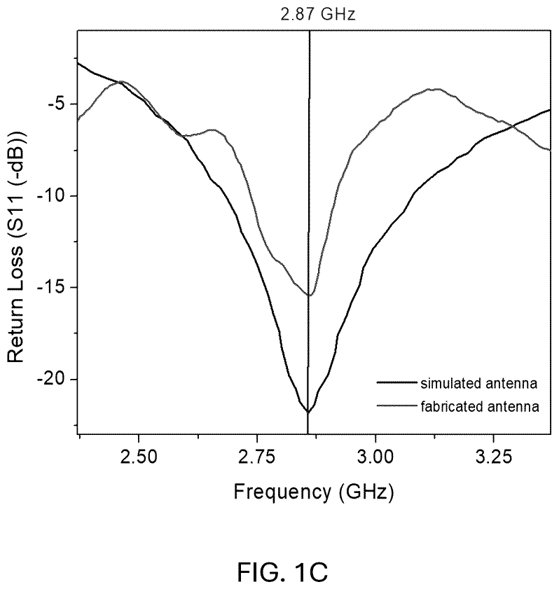

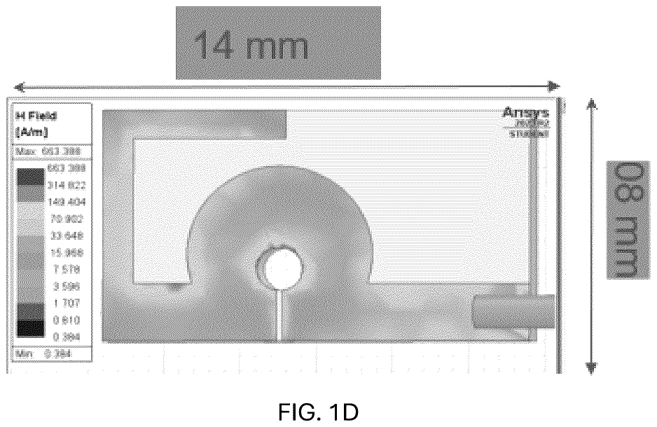

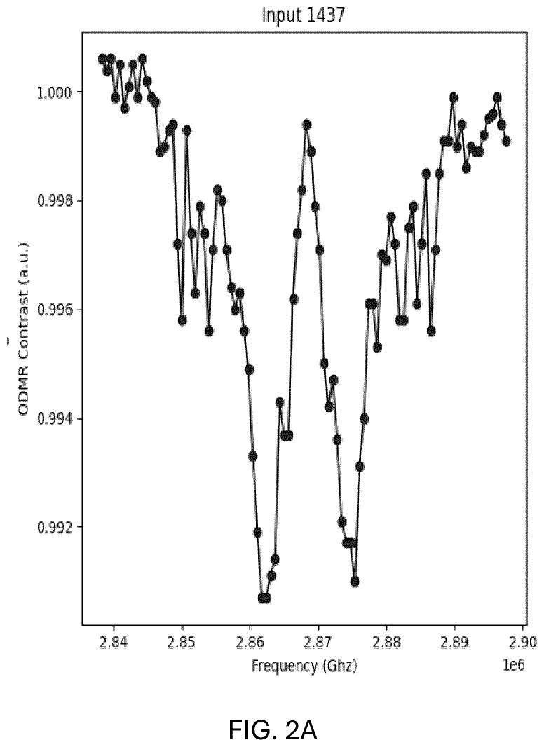

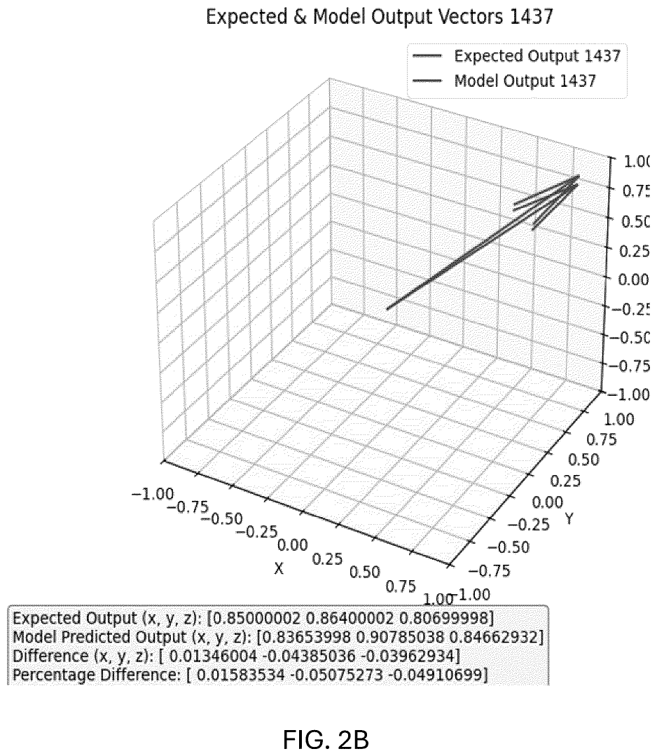

Referring to FIGS. 1A-1D, 2A and 2B, a first embodiment of a CQS according to the invention is described. According to this embodiment, off-the-shelf components may be employed and assembled into a housing for example as shown in FIG. 1A. In terms of portability/compactness, the size of the housing shown in FIG. 1A is 4″×4″×1.7″. The essential elements of the device include a computer processor, an RF signal generator, an RF amplifier, an RF switch, an analog to digital converter (ADC), a touchscreen display, and an optics module. The optics module (FIG. 1B) houses a laser, lenses, an RF antenna, a diamond sample, optical filters, and a photodiode. The magnetic field detection sensitivity of this embodiment is at the microtesla level using a continuous wave (CW) optically detected magnetic resonance (ODMR) method. A custom developed software controls all the components during experiments, stores the collected data into the memory of the internal computer and performs data analysis to extract the measured magnetic field magnitude. This software initiates the ODMR scans by setting the RF frequency while reading corresponding optical signal from the diamond. The collected RF frequency versus optical intensity data is recorded in the memory as a data file and an image along with scan parameters such as RF signal amplitude, scan speed, and number of data points per scan. The second part of the software extracts the magnetic field value by postprocessing the collected data.

Efficient delivery of microwave radiation to the samples is a critical aspect of solid-state defect-based quantum sensing experiments. Traditional approaches involve forming a wire loop at the tip of an RF cable and using gold wires as RF antennas. The present invention uses high efficiency microstrip and coplanar RF antennas where low level microwave power outputs are sufficient to observe ODMR and magnetic field sensing with NV defects in diamond. These antennas help to avoid unwanted effects, such as heating and interference, of RF signals on other circuit components of the device. FIG. 1C shows a simulated magnetic field image, simulated and experimental S11 data of an 8 mm×14 mm omega shaped coplanar RF antenna that has about −15 dB experimental return loss at 2.87 GHz zero field splitting (ZFS) frequency of NV diamond. FIG. 1D shows the antenna's dimensions and the simulated magnetic field image RF antennas with other geometries and dimensions can be built to improve the sensitivity of the CQS device.

As the CQS device of the invention is based on the NV diamond quantum sensing approach, it can perform vectorial magnetometry. FIG. 2A shows the ODMR spectra collected with a CQS device of the invention, in which ODMR spectra includes the signatures of the vectorial magnetic fields measured. A machine learning (ML) algorithm may be used to enhance the sensitivity of the CQS device and to predict the vectorial components of the measured magnetic fields. Machine learning regression, random forest, and neural network approaches are used in training machine learning models with large sets of ODMR scan data for vectorial magnetic field detection, which are collected with the CQS devices of the invention using Helmholtz coils. Trained models are tested with the other data sets that have not been used in the training process. CQS devices of the invention are capable of achieving nanotesla and even picotesla level magnetic field detection sensitivity with vectorial magnetic field detection accuracy close to 100%. FIG. 2B depicts the comparison of the expected vs ML predicted magnetic field vectors.

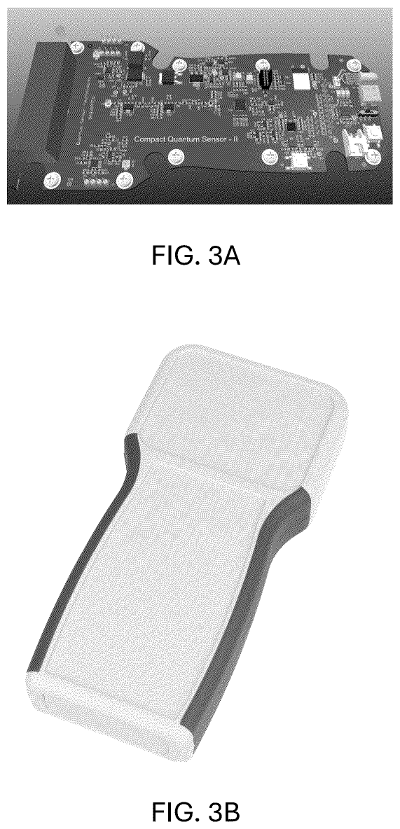

According to other embodiments of the invention, custom electronic components and a microcontroller may be used in a smaller off-the-shelf housing to further increase compactness and portability. The version shown in FIGS. 3A and 3B measures 6.5″×3.15″×1.1″, with a larger touchscreen display and longer battery life due to improved power management. This version is built by using components with identical functions of the off-the-shelf counterparts in the first embodiment. The computer is replaced with a microcontroller with custom firmware. The off-the-shelf laser driver is replaced with a more stable custom version. A custom battery control power management module was developed. Future iterations may involve components with superior stability and performance to improve the sensitivity of the CQS devices.

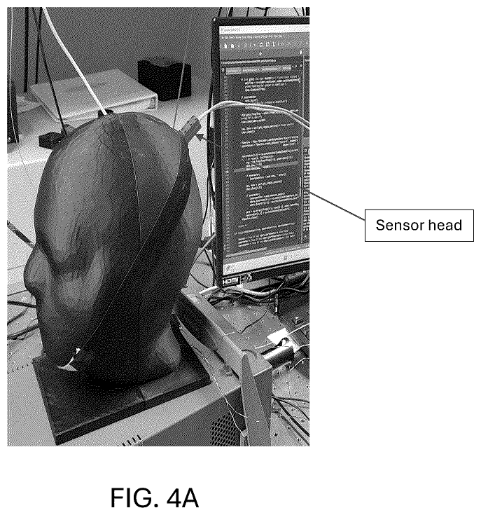

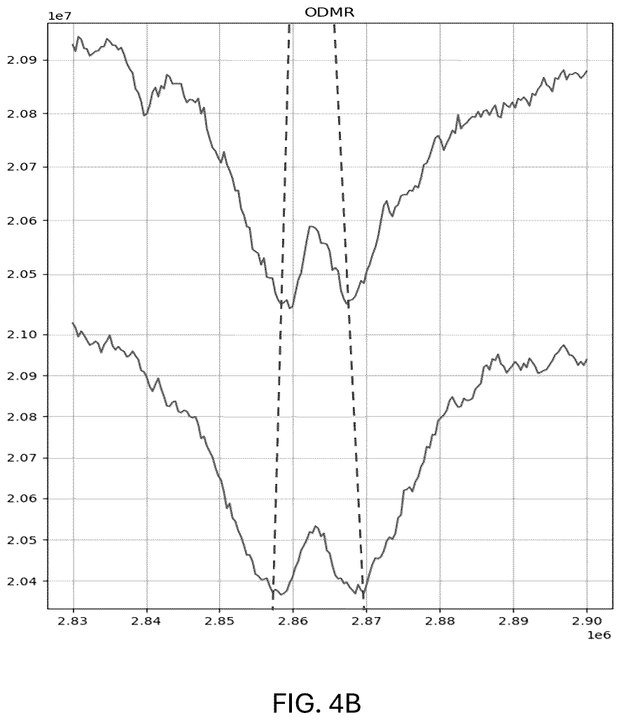

According to a further, more specialized embodiment of the invention, a special-purpose quantum sensor device with a small footprint sensor head (FIG. 4A) may be used for brain imaging through noninvasive detection of extracranial vector magnetic fields (MFs) generated by neural activities with the magnetoencephalography (MEG) method. According to this embodiment, the excitation laser, RF signal generator/amplifier, and spectrometers may be configured as external components, connected to the sensor head with an optical fiber and RF cable, with the RF antenna and the diamond sample placed in the sensor head. Alternatively, optical output may be collected at the sensor head with photodiode(s), removing the need for the optical fiber.

As with the previously described embodiments, this embodiment is also based on the nitrogen vacancy color centers in artificially grown diamonds. The optical fiber-based quantum sensor shown in FIG. 4A has a 10 mm×10 mm probe head that can be placed on a patient's head. This version was tested on a custom-built head phantom that simulates brain signals. The sensor footprint can be reduced to 5 mm×5 mm or smaller as required. Multiple electrodes can be attached to the patient's head due to the probe's small size. The device works under ambient conditions and does not require a shielded room, cooling and heating like the current MEGs and OPMs. One variation of this embodiment includes a battery-operated wearable helmet device with multiple electrodes. As shown in FIG. 4A and the data of FIG. 4B, the device has suitable dimensions for diagnostic intervention, and it can detect low level MF signals. Combination of the small head probe and the compact quantum sensor device allows for the use of highly sensitive magnetic field measurements in hard-to-reach areas. Femtotesla level MF detection is achieved using NV diamond approach with hardware and ML algorithms.

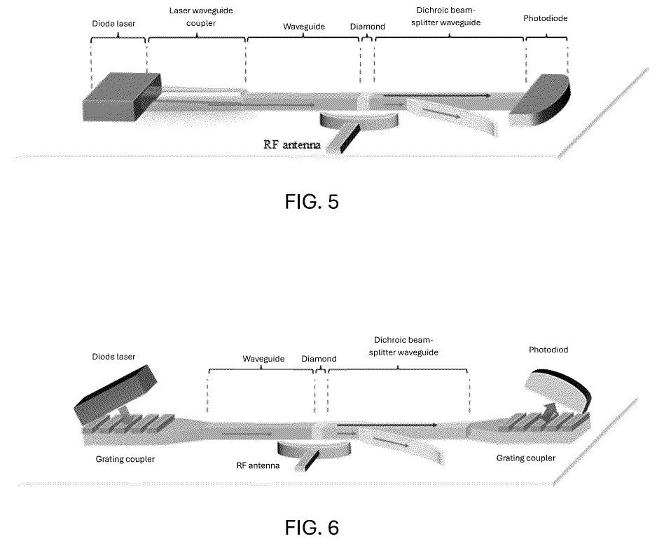

According to further embodiments of the invention, the CQS may employ photonic integrated circuit (PIC) components. In a first PIC implementation, the components of the CQS, including the laser diode and the photodetector, may be coplanar as shown in FIG. 5. In this configuration, a coplanar integrated 532 nm green diode laser output is directed into a waveguide through a tapered coupler. A waveguide fabricated by various methods, including metal oxide sputtering, couples the excitation laser to the NV diamond sample. RF signals can be applied to the RF antenna by on-board RF signal generators or external RF signal generators for NV defect electron spin manipulation. The dichroic beam splitter waveguide will couple the emitted red photons to the integrated coplanar photodetector, while deflecting and filtering the green excitation laser signal after the diamond. The photoluminescence intensity of the emitted light output from the photodetector will be used in quantum sensing of external changes in physical quantities.

Fabrication of the device of FIG. 5 may proceed as follows: diamond samples are etched to match the size of the waveguides with reactive ion etching using lithographic masks. Etching parameters and methods may be optimized to obtain smooth edges for increasing waveguide coupling efficiency. Waveguides and couplers are fabricated for excitation of the NV diamond sample and for photoluminescence (PL) signal collection using electron beam lithography, reactive ion etching, or other nanofabrication methods. The dichroic beam splitting waveguide on the PL collection side may be designed with computational simulations such as Finite Difference Time Domain (FDTD) approach. Bragg gratings and ring resonators may be also used for photonic beam splitting. 532 nm diode laser and photodiode are preferably fabricated on the same device which will be coupled to the waveguides. RF antennas are designed with electromagnetic simulations and fabricated directly on the device next to the diamond sample. RF signals will be applied by an onboard or external RF source.

According to an alternate PIC embodiment, the CQS device may employ PIC quantum magnetometers with grating coupled components. According to this embodiment, shown in FIG. 6, the diode laser and the photodiode are coupled to the excitation and PL collection waveguides through grating couplers on both ends of the device.

PIC based quantum sensor devices according to the invention will have smaller footprints due to photonic integrated approach with a volume of approximately 10 cm×4 cm×2 cm and weigh about 100 grams. The devices will also have a battery, and optionally include display and Bluetooth components.

1. A quantum sensing device comprising:
a power source,
a computer processor and non-transient memory,
an RF signal generator in electronic communication with the computer processor,
an RF amplifier in electronic communication with the computer processor,
an RF switch in electronic communication with the computer processor,
an analog-to-digital converter in electronic communication with the computer processor,
a display in electronic communication with the computer processor,
an input device in electronic communication with the computer processor,
an optics module, the optics module comprising.
a laser driver circuit in electronic communication with the computer processor,
a laser in electronic communication with the laser driver circuit,
at least one lens configured to focus excitation laser on the diamond sample,
a diamond located in an optical path of the laser,
at least one optical filter configured to filter the excitation laser, and
a photodiode configured to collect emitted signals by the diamond and in electronic communication with the computer processor or through the laser driver circuit via the analog-to-digital converter,
the non-transient memory containing computer readable instructions which when executed by the computer processor cause
power source to turn on the laser,
the display device to turn on and accept user instructions,
the RF signal generator to turn on and start the RF frequency sweep at a predetermined or user-selected amplitude,
the RF amplifier to power on,
the RF switch to allow applications of RF signals at predetermined or user-selected intervals,
the analog-to-digital converter to transmit converted digital signals at predetermined or user-selected intervals,
the optics module to perform ODMR measurements.

2. The quantum sensing device of claim 1, further comprising a housing having a size no greater than 23 cubic inches.

3. The quantum sensing device of claim 2, wherein said power source, said RF signal generator, said RF amplifier, said RF switch, said analog-to-digital converter, said display, said input device, and said optics module, are contained in or on said housing.

4. The quantum sensing device of claim 1, configured to detect microtesla level magnetic fields and their vectorial components.

5. The quantum sensing device of claim 1, configured to detect nanotesla level magnetic fields and their vectorial components.

6. The quantum sensing device of claim 1, configured to detect picotesla level magnetic fields and their vectorial components.

7. The quantum sensing device of claim 1, configured to detect femtotesla level magnetic fields and their vectorial components.

8. The quantum sensing device of claim 1, having a sensor head comprising said RF antenna and said diamond.

9. The quantum sensing device of claim 8, said sensor head connected to said spectrometer or photodiode by an optical fiber RF cable.

10. The quantum sensing device of claim 8, said sensor head further comprising a photodiode, said sensor head connected to said computer processor by an RF cable and other data cables.
